(19) United States
(12) Patent Application Publication
(10) Pub. No.: US 2026/0188969 A1
(43) Pub. Date: Jul. 2, 2026

(54) LASER SOURCE, FABRICATION METHOD AND IMAGING METHOD

(71) Applicant: Shanghai Tianma Micro-electronics Co., Ltd., Shanghai (CN)

(72) Inventors: Qijun YAO, Shanghai (CN); Yue XIE, Shanghai (CN)

(21) Appl. No.: 19/079,847

(22) Filed: Mar. 14, 2025

(30) Foreign Application Priority Data
Dec. 31, 2024 (CN) 202411998934.9

(51) Int. Cl. H01S 5/02255; G01S 7/481; G01S 17/894; G02B 5/04; H01S 5/0233; H01S 5/42

(52) U.S. Cl. CPC H01S 5/02255; G01S 7/4814; G01S 17/894; G02B 5/04; H01S 5/0233; H01S 5/423

(57) ABSTRACT

A laser source, a method for forming a laser source and an imaging method of a laser source are provided. The laser source includes a flexible substrate including a first surface and a second surface opposite to each other; a plurality of vertical-cavity surface-emitting laser source units arranged on the first surface of the flexible substrate and being arranged in rows and columns; and a prism structure attached to the flexible substrate. The first surface of the flexible substrate faces the prism structure, and the prism structure and the flexible substrate are bent toward the second surface of the flexible substrate.

### CROSS-REFERENCE TO RELATED APPLICATION

This application claims the priority of Chinese Patent Application No. 202411998934.9, filed on Dec. 31, 2024, the content of which is incorporated by reference in its entirety.

### TECHNICAL FIELD

The present disclosure generally relates to the field of laser source technologies and, more particularly, relates to a laser source, a fabrication method of a laser source and an imaging method.

### BACKGROUND

Vertical-cavity surface-emitting laser (VCSEL) is a special laser source. Its structure allows the light beam to be emitted vertically directly from the chip surface, which results in less energy loss and higher efficiency. This laser source is used in many fields, such as optical communications, optical storage, and medical fields.

The imaging effect of structured light radar devices using the laser emitted by the vertical-cavity surface-emitting laser source as the light source needs to be continuously improved. The present disclosed laser sources, fabrication methods of the laser sources and imaging methods of the laser sources are direct to solve such a problem and other problems in the art.

### SUMMARY

One aspect of the present disclosure provides a laser source. The laser source includes a flexible substrate including a first surface and a second surface opposite to each other; a plurality of vertical-cavity surface-emitting laser source units arranged on the first surface of the flexible substrate and being arranged in rows and columns; and a prism structure attached to the flexible substrate. The first surface of the flexible substrate faces the prism structure, and the prism structure and the flexible substrate are bent toward the second surface of the flexible substrate.

Another aspect of the present disclosure provides a method for forming a laser source. The method includes providing a flexible substrate including a first surface and a second surface opposite to each other; providing a plurality of vertical-cavity surface-emitting laser source units; performing a mass transfer process to arrange the plurality of vertical-cavity surface-emitting laser source units on the first surface of the flexible substrate, and distribute the plurality of vertical-cavity surface-emitting laser source units in rows and columns; providing a prism structure, and fitting the prism structure to the flexible substrate with the first surface of the flexible substrate facing the prism structure; and bending the prism structure and the flexible substrate toward the second surface of the flexible substrate.

Another aspect of the present disclosure provides an imaging method of a laser source. The imaging method includes providing a laser source. The laser source includes a flexible substrate including a first surface and a second surface opposite to each other; a plurality of vertical-cavity surface-emitting laser source units arranged on the first surface of the flexible substrate and being arranged in rows and columns; and a prism structure attached to the flexible substrate. The first surface of the flexible substrate faces the prism structure, and the prism structure and the flexible substrate are bent toward the second surface of the flexible substrate. The imaging method also includes imaging a static object according to the laser source; and imaging a dynamic object according to the laser source.

Other aspects of the present disclosure can be understood by those skilled in the art in light of the description, the claims, and the drawings of the present disclosure.

### BRIEF DESCRIPTION OF THE DRAWINGS

To illustrate the technical solutions in the embodiments of the present disclosure more clearly, the following briefly introduces the accompanying drawings used in the description of the embodiments. Obviously, the accompanying drawings in the following description are only some embodiments of the present disclosure, for those of ordinary skill in the art, other drawings can also be obtained from these drawings without creative effort.

FIG. 1 illustrates the optical path of a vertical-cavity surface-emitting laser source after emitting laser;

FIGS. 2-7 illustrate structures of an exemplary laser source according to various embodiments of the present disclosure;

FIGS. 8-10 illustrate structures of another exemplary laser source according to various embodiments of the present disclosure;

FIG. 11 illustrates a flowchart of an exemplary fabrication method of a laser source according to various embodiments of the present disclosure;

FIG. 12 illustrates another exemplary laser source according to various embodiments of the present disclosure; and

FIGS. 13-16 illustrate an exemplary imaging method of a laser source according to various embodiments of the present disclosure.

### DETAILED DESCRIPTION

As described in the background technology, the imaging effect of the structured light radar device using the laser emitted by the vertical-cavity surface-emitting laser source as the light source needs to be continuously improved.

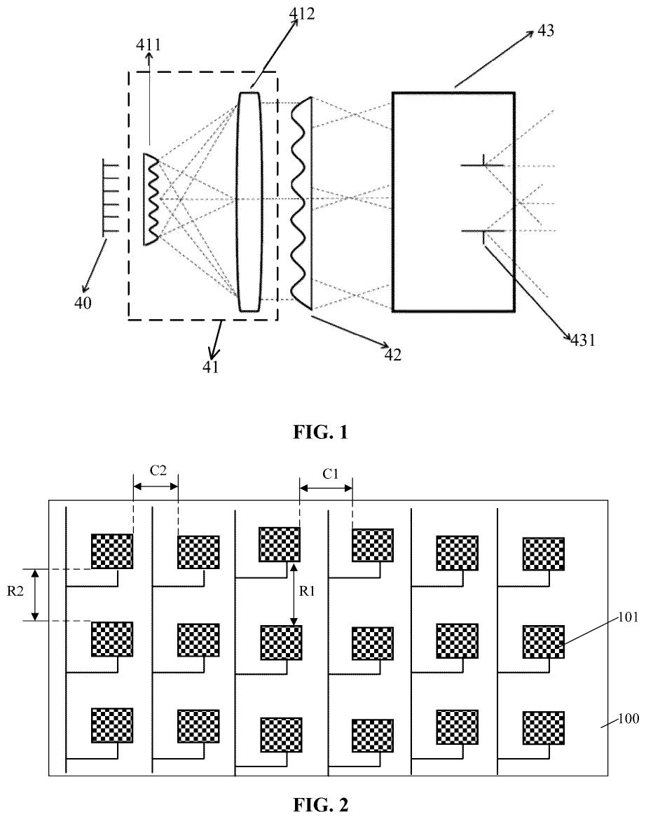

FIG. 1 is a schematic diagram of the optical path of a vertical-cavity surface-emitting laser source after emitting light. As shown in FIG. 1, the optical path after the vertical-cavity surface emitting laser source emits the laser may include that after the vertical-cavity surface-emitting laser source 40 (VCSEL) emits the light, the beam may be shaped by the beam shaper 41 (Beam Shaper), and then the laser direction may be further adjusted by the DOE diffraction grating 42, and then the adjusted light may be emitted by the optical projection lens 43 (Projection Lens). The optical projection lens 43 may include a beam outlet 431, and the adjusted light may be emitted through the beam outlet 431.

The beam shaper 41 may include an optical beam expander 411 (Beam Homogenizer) and an optical collimator 412 (Collection Lens). The optical beam expander 411 may be used to disperse the laser and process the laser into stripes or dots. The optical collimator 412 may be used to collimate the dispersed laser.

The imaging principle of the vertical-cavity surface-emitting laser source may be that the dispersed stripes or dots are projected onto the surface of the object and then be reflected. The laser receiver may receive the reflected laser and calculate the distance between the object and the light source. When the laser is projected onto the surface of a three-dimensional object, the height of the physical surface may be inferred based on the change of the light source pattern.

However, after the laser source is processed into stripes or dots, the light intensity of the light source may be relatively dispersed, and the reflected light of the distant object is not strong enough, so it may be difficult to image.

To solve the above problems, the technical solution of the present disclosure provides a laser source, a fabrication method of the laser source and an imaging method. By arranging a plurality of vertical-cavity surface-emitting laser source units in rows and columns on a flexible substrate, the prism structure and the flexible substrate may be bent toward the second surface of the flexible substrate. On the one hand, the second surface of the flexible substrate is bent, and the light emitted by the plurality of vertical-cavity surface-emitting laser source units distributed on the second surface of the flexible substrate may cover a larger angle distribution range, so that the light-emitting angle of the laser source as a whole may be increased, and objects within a larger range may be covered, thereby increasing the imaging range. On the other hand, each vertical-cavity surface-emitting laser source unit may emit light, so each light spot may come from a corresponding light source of a vertical-cavity surface-emitting laser source unit, and the single-point light spot light may be strong enough, and a complex optical system of the light source may not be required, thereby improving the stability of the system. On the other hand, the prism structure may further disperse the light emitted by each laser source unit, further increasing the light-emitting angle of the laser source as a whole, thereby increasing the imaging range.

To make the above-mentioned purposes, features and beneficial effects of the present disclosure more obvious and easy to understand, the specific embodiments of the present disclosure are described in detail below in conjunction with the accompanying drawings.

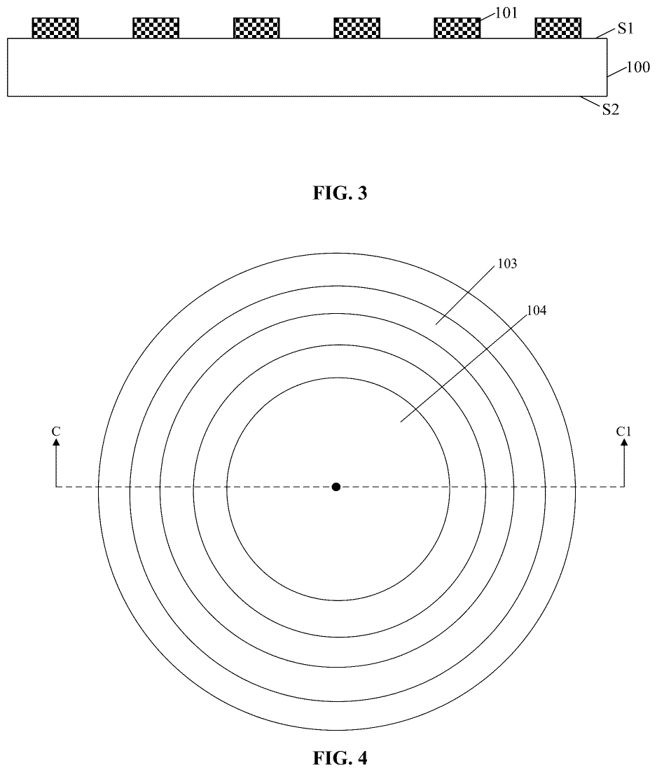

FIGS. 2-7 are schematic diagrams of the structure of an exemplary laser source according to various embodiments of the present disclosure. As shown in FIGS. 2-7, the laser source may include a flexible substrate 100. The flexible substrate 100 may include a first surface S1 and a second surface S2 opposite to each other.

The laser source may also include a plurality of vertical-cavity surface-emitting laser source units 101 arranged on the first surface S1 of the flexible substrate 100. The plurality of vertical-cavity surface-emitting laser source units 101 may be distributed in rows and columns.

Further, the laser source may include a prism structure 102 attached to the flexible substrate 100. The first surface S1 of the flexible substrate 100 may face the prism structure 102, and the prism structure 102 and the flexible substrate 100 may be bent toward the second surface S2 of the flexible substrate 100.

In the laser source, the plurality of vertical-cavity surface-emitting laser source units 101 may be distributed in rows and columns, and the prism structure 102 and the flexible substrate 100 may be bent toward the second surface S2 of the flexible substrate 100. On the one hand, the second surface S2 of the flexible substrate 100 may be bent, and the light emitted by the plurality of vertical-cavity surface-emitting laser source units distributed on the second surface S2 of the flexible substrate 100 may cover a larger distribution range, so that the light-emitting angle of the laser source as a whole may be increased, and objects within a larger range may be covered, thereby increasing the imaging range. On the other hand, each vertical-cavity surface-emitting laser source unit may emit light, so each light spot may come from a corresponding unit light source of a vertical-cavity surface-emitting laser light source, and the single-point light spot light may be strong enough, and a complex optical system of the light source may not be required, thereby improving the stability of the system. On the other hand, the prism structure 102 may further disperse the light emitted by each vertical-cavity surface-emitting laser source unit 101, further increasing the light-emitting angle of the laser source as a whole, thereby increasing the imaging range.

FIGS. 2-3 are schematic diagrams of the structure of the un-bent flexible substrate 100 and the plurality of vertical-cavity surface-emitting laser source units 101 arranged in an array on the flexible substrate 100. FIG. 2 is a top view of the first surface S1 in FIG. 3, and FIG. 3 is a side view of FIG. 2.

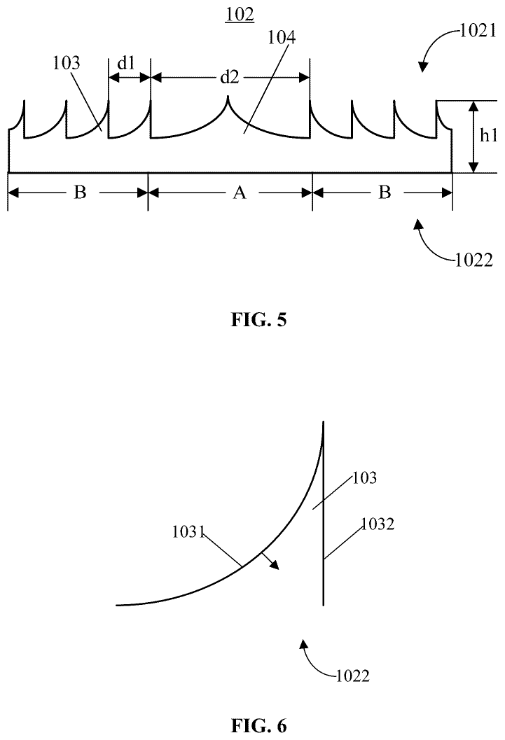

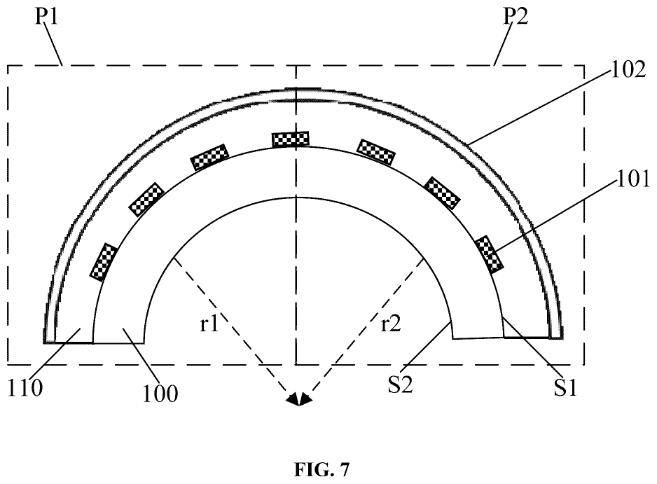

FIGS. 4-6 are schematic diagrams of the structure of the un-bent prism structure 102. FIG. 4 is a top view of the prism structure 102. FIG. 5 is a schematic diagram of the cross-sectional structure of FIG. 4 along the section line CC1. FIG. 6 is an enlarged schematic diagram of the first sawtooth in FIG. 5. As shown in FIGS. 5-6, the prism structure 102 may include a central area A and a threaded area B surrounding the central area A. The prism structure 102 may include a functional surface 1021 and a relative non-functional surface 1022. The non-functional surface 1022 may be used to fit with the flexible substrate 100.

The prism structure 102 may be used to further diffract the light emitted by the plurality of vertical-cavity surface-emitting laser source units 101, increase the degree of light dispersion, and improve the imaging range.

In one embodiment, the functional surface 1021 of the threaded area B may include a plurality of raised rings 103. The plurality of raised rings 103 may surround the central area A, and the plurality of raised rings 103 may be distributed in concentric rings. The functional surface 1021 of the central area A may include a convex transparent structure 104.

In one embodiment, the widths of the plurality of raised rings 103 may be same. The widths of the plurality of raised rings 103 may be the same, so that the prism structure 102 may be easy to form.

In other embodiments, the widths of the plurality of raised rings may not be the same.

The plurality of raised rings may be independent lens, each of which may have a different focal length. According to the angle and range of the diffraction of the light required by the vertical-cavity surface-emitting laser source unit 101 corresponding to the raised ring 103, the widths of the plurality of raised rings may be adjusted to be completely the same or not completely the same according to the design requirements, so as to ensure that the light emitted by the vertical-cavity surface-emitting laser source unit 101 may have a wide angle diffraction range and the imaging range may be improved.

In one embodiment, the cross-sectional shape of the plurality of raised rings 103 may include a first sawtooth shape.

As shown in FIG. 6, in one embodiment, the first sawtooth may include a tooth back 1031 and a tooth throat 1032. The tooth back 1031 of the first sawtooth may be concave toward the non-functional surface 1022.

In other embodiments, the tooth back of the first sawtooth may be convex in a direction away from the functional surface.

The non-functional surface 1022 of the prism structure 102 may be fitted with the flexible substrate 100, and the back of the first sawtooth may be concave and convex. The back of the first sawtooth may be adjusted to be concave and convex according to the angle and range of the diffraction of the light required for the number of vertical-cavity surface-emitting laser source units 101, so as to ensure that the light emitted by the vertical-cavity surface-emitting laser source unit 101 may have a wide angle diffraction range to improve the imaging range.

In one embodiment, the cross-sectional shape of the convex transparent structure 104 may include a second sawtooth shape, and the width d2 of the second sawtooth may be greater than the width d1 of the first sawtooth.

The width d2 of the second sawtooth may be the width of the central area A along the surface of the flexible substrate 100, and the width d1 of the first sawtooth may be the width of the raised ring 103 along the surface of the flexible substrate 100.

Referring to FIG. 2, in one embodiment, the plurality of vertical-cavity surface-emitting laser source units 101 corresponding to the central area A may have a first row spacing R1 and a first column spacing C1, and the plurality of vertical-cavity surface-emitting laser source units 101 corresponding to the threaded area B may have a second row spacing R2 and a second column spacing C2.

In this embodiment, the first row spacing R1 may be different from the second row spacing R2, and the first column spacing C1 may be different from the second column spacing C2. Thus, the arrangement of the plurality of vertical-cavity surface-emitting laser source units 101 may be adjusted according to the width of the central area A and the width of the threaded area B, according to the curvature of the central area A and the curvature of the threaded area B, or according to the required light-emitting angle of the vertical-cavity surface-emitting laser source unit 101, so that the application of the laser source may be more flexible.

In one embodiment, the first row spacing R1 may be greater than the second row spacing R2; and the first column spacing C1 may be greater than the second column spacing C2. In other embodiments, the row spacing between several rows of the vertical-cavity surface-emitting laser source units may be the same; and the column spacing between several columns of the vertical-cavity surface-emitting laser source units may be the same. Therefore, the vertical-cavity surface-emitting laser source units distributed in an array may be easy to layout and design, may save the layout area, and may be easy to operate when being transferred through a mass transfer process.

In this embodiment, the thickness h1 range of the prism structure 102 may be greater than or equal to 1 mm. The prism structure 102 in such a thickness range may have sufficient strength when being bent while maintaining the effect of light diffraction.

The thickness h1 of the prism structure 102 may be the distance between the highest point of the convex transparent structure 104 and the non-functional surface 1022, or the distance between the highest point of the raised ring 103 and the non-functional surface 1022.

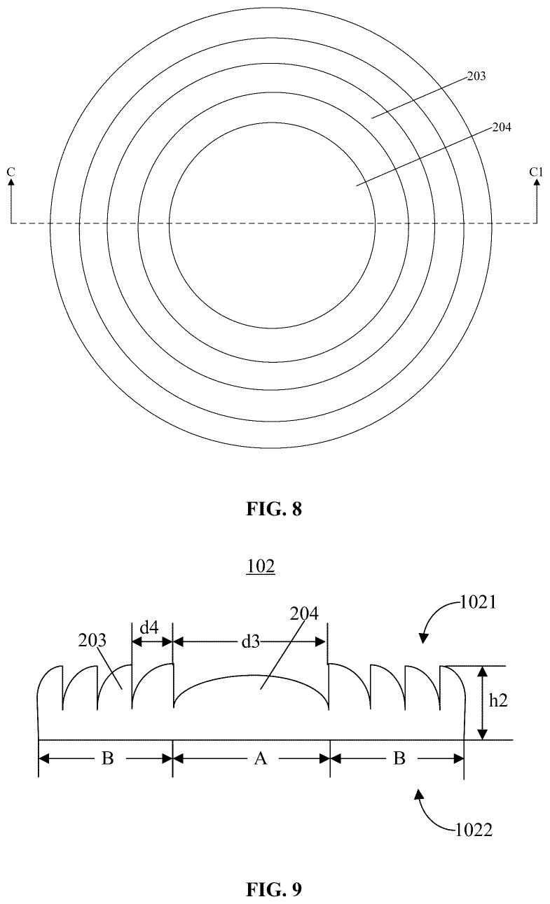

FIG. 7 is a schematic diagram of the structure of the flexible substrate 100 and the prism structure 102 attached to the flexible substrate 100 bent toward the second surface S2 of the flexible substrate 100. As shown in FIG. 7, the non-functional surface 1022 of the prism structure 102 may be attached to the first surface S1 of the flexible substrate 100, and the laser source may include a first part P1 and a second part P2. The interface between the first part P1 and the second part P2 may be a central plane perpendicular to the surface of the flexible substrate 100.

The prism structure 102 and the flexible substrate 100 may be bent toward the second surface S2 of the flexible substrate 100, and the radius of the curvature may range from 1 cm to 10 cm. In one embodiment, the radius of the curvature r1 of the first part P1 may be different from the radius of the curvature r2 of the second part P2. In another embodiment, the radius of the curvature r1 of the first part P1 and the radius of the curvature r2 of the second part P2 may be the same.

The radius of the curvature r1 of the first part P1 and the radius of the curvature r2 of the second part P2 may be the same or different, and the light-emitting angle of several vertical-cavity surface-emitting laser source units 101 may be flexibly adjusted by adjusting the radius of the curvature r1 of the first part P1 and the radius of the curvature r2 of the second part P2, so that the light-emitting angle of the laser source may be increased.

Further, referring to FIG. 2, the laser source may also include a plurality of thin-film transistors arranged on the first surface S1 of the flexible substrate 100. The plurality of thin-film transistors may be electrically connected to the plurality of vertical-cavity surface-emitting laser source units 101, and the plurality of thin-film transistors may be used to control the switch of the plurality of vertical-cavity surface-emitting laser source units 101.

In one embodiment, the plurality of vertical-cavity surface-emitting laser source units 101 may be distributed in rows and columns, the vertical-cavity surface-emitting laser source units 101 in each column may be electrically connected, and the vertical-cavity surface-emitting laser source units 101 in each row may be electrically connected, so that the vertical-cavity surface-emitting laser source units 101 in one row and one column may be controlled separately, so that the plurality of vertical-cavity surface-emitting laser source units 101 may emit light according to the set timing.

Further, referring to FIG. 7, the laser source may also include an optical glue layer 110 disposed between the first surface S1 of the flexible substrate 100 and the prism structure 102. The optical glue layer 110 may be used to glue the prism structure 102 to the flexible substrate 100. The optical glue layer 110 may also cover the top plate surface and the side wall surface of the plurality of vertical-cavity surface-emitting laser source units 101.

In one embodiment, the thickness of the optical glue layer 110 may be greater than the thickness of the vertical-cavity surface-emitting laser source unit 101. Thus, the optical glue layer 110 may protect the vertical-cavity surface-emitting laser source unit 101, and prevent the vertical-cavity surface-emitting laser source unit 101 from being damaged when the flexible substrate 100 and the prism structure 102 are attached.

In one embodiment, the transmittance of the optical glue layer 110 may be greater than 90%. The transmittance of the optical glue layer 110 may be relatively large, so that when the vertical-cavity surface-emitting laser source unit 101 emits light, the light loss may be reduced.

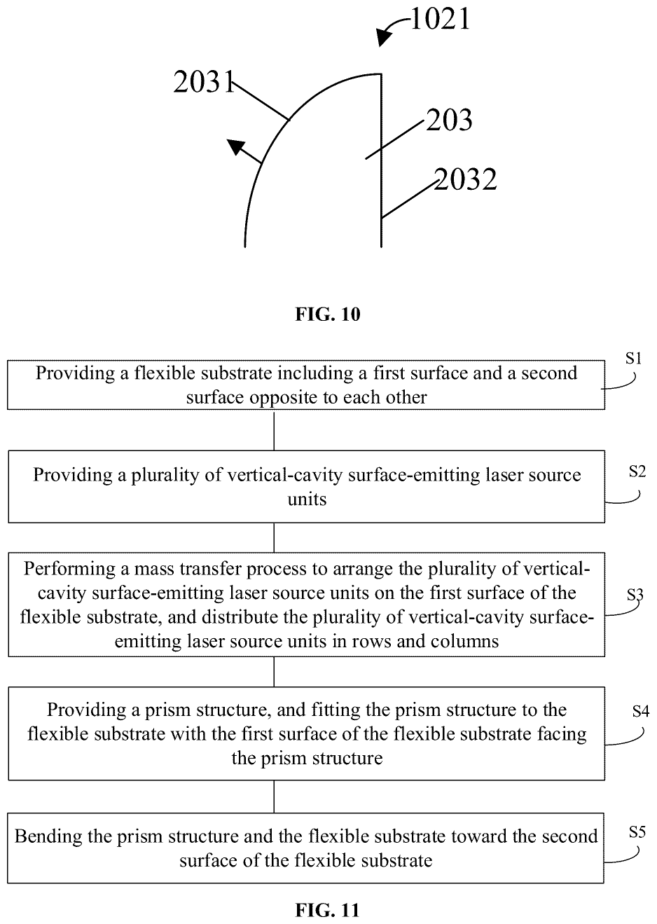

FIGS. 8-10 are schematic diagrams of the structure of another laser source according to various embodiments of the present disclosure. FIGS. 8-10 illustrate the schematic diagrams of the structure of the prism structure 102 without bending. FIG. 8 is a top view of the prism structure 102, FIG. 9 is a schematic diagram of the cross-sectional structure of FIG. 8 along the section line CC1, and FIG. 10 is an enlarged schematic diagram of the first sawtooth in FIG. 9. As shown in FIG. 9, the prism structure 102 may include a central area A and a threaded area B surrounding the central area A. Further, the prism structure 102 may include a relative functional surface 1021 and a non-functional surface 1022. The non-functional surface 1022 may be used to fit with the flexible substrate 100.

In one embodiment, the functional surface 1021 of the threaded area B includes a plurality of raised rings 203, and the plurality of raised rings 203 surround the central area A, and the plurality of raised rings 203 may be distributed in concentric rings. The functional surface 1021 of the central area A may include a convex transparent structure 204.

The difference between the prism structure 102 in FIGS. 8-10 and the prism structure 102 in FIGS. 4-6 may include that, the cross-sectional shape of plurality of the raised rings 103 may include a first sawtooth shape. The first sawtooth may include a tooth back 2031 and a tooth throat 2032. The tooth back 2031 of the first sawtooth may protrude in a direction away from the functional surface 1021. The cross-sectional shape of the convex transparent structure 204 may include a half-circle.

In one embodiment, the width d3 of the first sawtooth may be less than the width d4 of the convex transparent structure 204. The width d4 of the convex transparent structure 204 may be the width of the central area A along the surface of the flexible substrate 100, and the width d3 of the first sawtooth may be the width of the raised ring 103 along the surface of the flexible substrate 100.

In one embodiment, the thickness h2 of the prism structure 102 may be greater than or equal to 1 mm. The prism structure 102 in such a thickness range may have sufficient strength when being bent while maintaining the effect of light diffraction.

The thickness h2 of the prism structure 102 may be the distance between the highest point of the convex transparent structure 204 and the non-functional surface 1022, or the distance between the highest point of the raised ring 203 and the non-functional surface 1022.

By adjusting the shapes of the raised ring 203 and the convex transparent structure 204 on the surface of the prism structure 102, the dispersion degree of the light emitted by the plurality of vertical-cavity surface-emitting laser source units 101 may be adjusted, so that the light-emitting angle of the laser source may be increased.

The present disclosure also provides a method for forming a laser source. FIG. 11 illustrates a flow chart of an exemplary fabrication method of a laser source according to various embodiments of the present disclosure.

As shown in FIG. 11, the method for forming the laser source may include:
Step S1: providing a flexible substrate 100 as shown in FIG. 2 and FIG. 3. The flexible substrate 100 may include a first surface S1 and a second surface S2 opposite to each other;
Step S2: providing a plurality of vertical-cavity surface-emitting laser source units 101 as shown in FIG. 2 and FIG. 3;
Step S3: using a mass transfer process to arrange the plurality of the vertical-cavity surface-emitting laser source units 101 on the first surface S1 of the flexible substrate 100. The plurality of the vertical-cavity surface-emitting laser source units 101 may be distributed in rows and columns;
Step S4: providing a prism structure 102 and fitting the prism structure 102 to the flexible substrate 100. The first surface S1 of the flexible substrate 100 may face the prism structure 102; and
Step S5: bending the prism structure 102 and the flexible substrate 100 toward the second surface S2 of the flexible substrate 100.

In one embodiment, the mass transfer process may be used to transfer the plurality of vertical-cavity surface-emitting laser source units 101 to the first surface S1 of the flexible substrate 100, thereby improving production efficiency.

In one embodiment, the prism structure 102 may be bonded to the flexible substrate 100 by an optical glue layer, and the optical glue layer may have a high transmittance to minimize light loss. In one embodiment, the optical glue may be an ultraviolet optical glue, which may be cured under the action of ultraviolet light to achieve the purpose of bonding the prism structure 102 with the flexible substrate 100.

In one embodiment, the prism structure 102 may be the prism structure 102 described in FIGS. 4-6, or the prism structure 102 may be the prism structure 102 described in FIGS. 8-10.

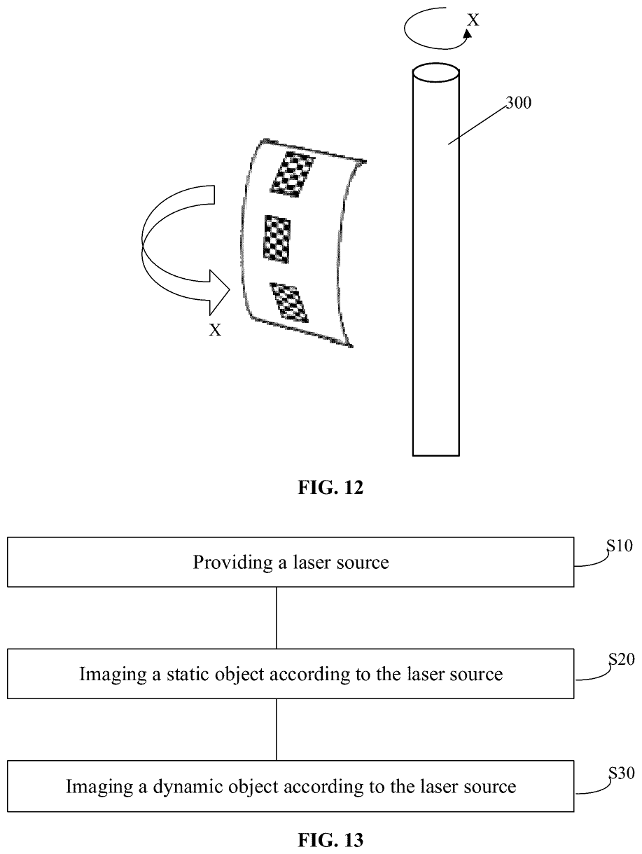

FIG. 12 illustrates a schematic diagram of the structure of another exemplary laser source according to various disclosed embodiments. FIG. 12 is a schematic diagram based on FIG. 7.

As shown in FIG. 12 and FIG. 7, the laser source may further include a rotation structure 300. The flexible substrate 100 may be arranged on the surface of the rotation structure 300, and the flexible substrate 100 may partially surround the surface of the rotation structure 300 or fully surround the surface of the rotation structure 300 along the rotation direction X of the rotation structure 300.

In one embodiment, the rotation structure 300 may include a rotation shaft. In other embodiments, the rotation mechanism may also be other structures that meet the conditions.

In one embodiment, the second surface S2 of the flexible substrate 100 may be bonded to the rotation structure 300 by solid optical glue or other non-optical glues including thermosetting glue, etc.

The curved flexible substrate 100 and the prism structure 102 may be bonded to the surface of the rotation structure 300, and the rotation shaft 300 may rotate in any direction, so that the light emitted by the laser light source may achieve any emission angle, forming an omnidirectional light source, which may be conducive to dynamic imaging of objects.

The present disclosure also provides an imaging method of a laser source. FIGS. 13-16 illustrate flow charts of exemplary imaging methods of a laser source according to various embodiments of the present disclosure.

As shown in FIG. 13, the imaging method of the laser source may include:
Step S10: providing a laser source;
Step S20: imaging a static object according to the laser source; and
Step S30: imaging a dynamic object according to the laser source.

The laser source in step S10 may be the laser source described in FIGS. 2-6, or the laser source described in FIGS. 7-8, or the laser source described in FIG. 10.

The laser source may include a vertical-cavity surface-emitting laser source unit with various emission angles, each light spot may come from a light source, and the single-point light spot light may be strong enough and easy to image. In addition, the single-point light spot light may be strong enough and not scattered, so that the imaging process of the plurality of vertical-cavity surface-emitting laser source units may speed up the calculation speed of the radar and improve efficiency.

Referring to FIG. 13, after providing the laser source, the Step S20 may be executed, which may include imaging a static object according to the laser source.

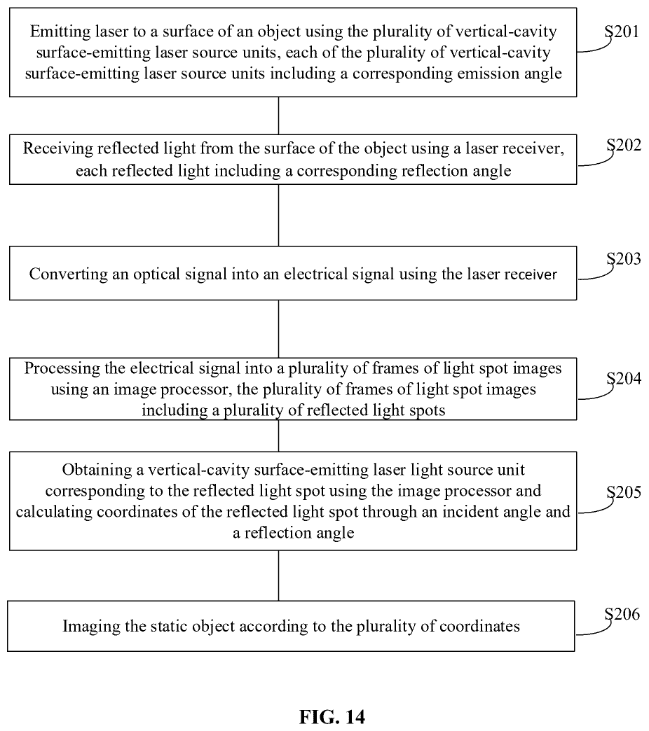

Further, referring to FIG. 14, in one embodiment, imaging a static object according to a laser source may include:
Step S201: the plurality of vertical cavity surface-emitting laser source units may emit laser to the surface of the object, and each vertical-cavity surface-emitting laser source unit may have a corresponding emission angle;
Step S202: a laser receiver may receive reflected light from the surface of the object, and each reflected light may have a corresponding reflection angle;
Step S203: the laser receiver may convert the optical signal into an electrical signal;
Step S204: the image processor may process the electrical signal into a plurality of frames of light spot images, and the light spot images include a plurality of reflected light spots;
Step S205: the image processor may obtain the vertical-cavity surface-emitting laser source unit corresponding to the reflected light spot, and calculate the coordinates of the reflected light spot through the incident angle and the reflection angle; and
Step S206: a static object may be imaged according to a plurality of coordinates.

According to the laser source described in FIGS. 2-7, or the laser source described in FIGS. 8-10, or the laser source in FIG. 12, a static object may be imaged. Each light spot may come from a light source of a vertical-cavity surface-emitting laser light source unit. The single-point light spot may be strong enough. Each light spot may have a different emission angle. The emission angle of each light spot may be calculated by the arrangement of the light spots. The depth coordinate of the reflection point may be calculated in combination with the imaging angle, and then the image may be formed.

During the imaging process of the static objects, the vertical-cavity surface-emitting laser source unit array may be driven to emit light by scanning, that is, the vertical-cavity surface-emitting laser source unit array may receive data line by line, and may not emit light at the moment of receiving data. After receiving the data, it may be turned on or off according to the received data before the next round of data arrives. From the perspective of video recording, the camera may also obtain data by scanning. The scanning may obtain the total amount of light signals captured within one frame. When the display and video scanning speeds are close, the situation that the vertical-cavity surface-emitting laser source does not emit light during the period of receiving data may have basically no effect on the captured signal, while turning it on or off according to the data may affect the brightness of 1˜2 frames.

The process in which the plurality of vertical-cavity surface-emitting laser source units emit lasers may include that the plurality of vertical-cavity surface-emitting laser source units emit laser at the same time, or the plurality of vertical-cavity surface-emitting laser source units emit lasers in sequence.

In one embodiment, the plurality of vertical-cavity surface-emitting laser source units emit lasers in sequence, and each vertical-cavity surface-emitting laser source unit may have a corresponding light emission sequence.

In the process of static object imaging, the plurality of vertical-cavity surface-emitting laser source units may emit light in sequence. By setting different light emission sequences for each vertical-cavity surface-emitting laser source unit, the position of each light spot may be calculated. For example, if there are 1,000 light spots, the position may be distinguished by about 10 frames of data, and the light emission sequence of a spot may be calculated based on the history of light emission of a light spot at a certain position, so as to find the corresponding vertical-cavity surface-emitting laser source unit.

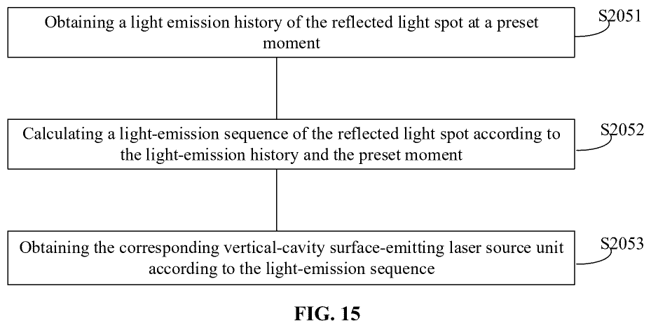

Further, referring to FIG. 15, in one embodiment, the process for the imaging processor to obtain the vertical-cavity surface-emitting laser source unit corresponding to the reflected light spot may include:
Step S2051: obtaining the light-emission history of the reflected light spot at a preset time;
Step S2052: calculating the light-emission timing of the reflected light spot according to the light-emission history and the preset time; and
Step S2053: obtaining the corresponding vertical-cavity surface-emitting laser source unit according to the light-emission timing.

A plurality of vertical-cavity surface-emitting laser source units may be provided with a prism structure outside. The light emitted by the vertical-cavity surface-emitting laser light unit may be dispersed after passing through the prism structure. In fact, the light incident on the surface of the object by a vertical-cavity surface-emitting laser source unit may include many incident angles. According to the correspondence between the incident angles and the vertical-cavity surface-emitting laser source unit, that is, a calibration test may be performed when the image source leaves the factory, and the reflected images of all light spots may be captured on a plane at a specific distance, and the emission angle of each point may be inferred from the positions of the images.

Further, referring to FIG. 13, the step S30: imaging the dynamic object according to the laser source, may be executed.

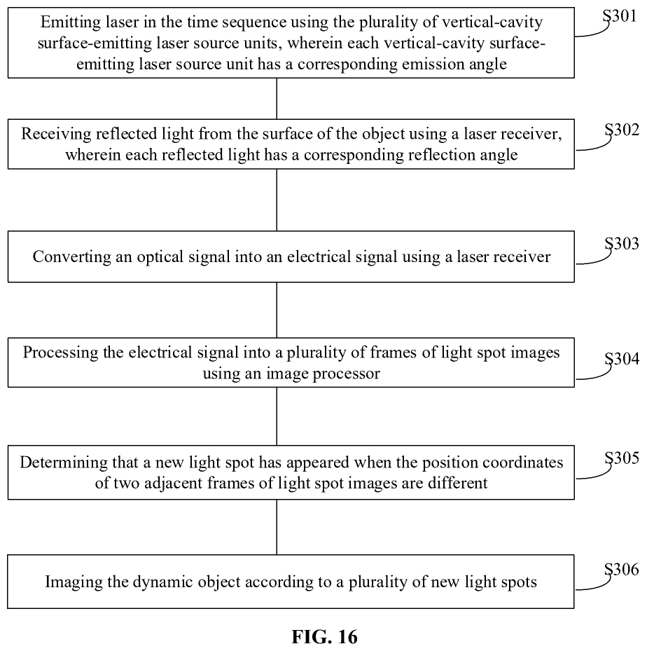

Further, referring to FIG. 16, in one embodiment, imaging the dynamic object according to the laser light source may include:
Step S301: a plurality of the vertical cavity surface-emitting laser source units may emit laser in sequence, and each vertical-cavity surface-emitting laser source unit may have a corresponding emission angle;
Step S302: a laser receiver may receive reflected light from the surface of the object, and each reflected light may have a corresponding reflection angle;
Step S303: the laser receiver may convert the optical signal into an electrical signal;
Step S304: an image processor may process the electrical signal into a plurality of frames of light spot images;
Step S305: when the position coordinates of two adjacent frames of light spot images are different, it may be determined that a new light spot has appeared; and
Step S306: the dynamic object may be imaged according to a plurality of new light spots.

The dynamic imaging process of the laser source may be easy to obtain and the imaging process may be easy.

The technical solutions of the present disclosure may include the following beneficial effects.

In the laser source of the present disclosure, a plurality of vertical-cavity surface-emitting laser source units may be distributed on the flexible substrate in rows and columns, and the prism structure and the flexible substrate may be bent toward the second surface of the flexible substrate. On the one hand, the second surface of the flexible substrate may be bent, and the light emitted by several vertical-cavity surface-emitting laser source units distributed on the second surface of the flexible substrate may cover a larger angle distribution range, so that the light-emitting angle of the laser source as a whole may be increased, and objects within a larger range may be covered, thereby increasing the imaging range; on the other hand, each vertical-cavity surface-emitting laser source unit may emit light, so each light spot may come from a light source of a corresponding vertical-cavity surface-emitting laser light source unit, and the single-point light spot light may be strong enough, and a complex optical system of the light source may not be required, thereby improving the stability of the system; on the other hand, the prism structure may further disperse the light emitted by each laser source unit, further increasing the light emitting angle of the laser source as a whole, thereby increasing the imaging range.

Furthermore, the curved flexible substrate and the prism structure may be attached to the surface of the rotation structure, and the rotation axis may rotate in any direction, so that the light emitted by the laser source may achieve any emission angle, forming an omnidirectional light source, which may be conducive to dynamic imaging of objects.

In the imaging method of the laser source of the present disclosure, the laser source may have a vertical-cavity surface-emitting laser source unit with various emission angles, each light spot may come from a light source, and the single-point light spot light may be strong enough and easy to image. Further, the single-point light spot light may be strong enough and not dispersed, so that the imaging process of the plurality of vertical-cavity surface-emitting laser source units may speed up the calculation speed of the radar and improve efficiency.

Although the present disclosure is disclosed as above, the present disclosure is not limited thereto. Any person skilled in the art may make various changes and modifications without departing from the spirit and scope of the present disclosure. Therefore, the protection scope of the present disclosure shall be subject to the scope defined by the claims.

What is claimed is:

1. A laser source, comprising:
a flexible substrate including a first surface and a second surface opposite to each other;
a plurality of vertical-cavity surface-emitting laser source units arranged on the first surface of the flexible substrate and being arranged in rows and columns; and
a prism structure attached to the flexible substrate,
wherein the first surface of the flexible substrate faces the prism structure, and the prism structure and the flexible substrate are bent toward the second surface of the flexible substrate.

2. The laser source according to claim 1, wherein the prism structure comprises:
a central area;
a threaded area surrounding the central area,
wherein:
the prism structure includes a functional surface and a non-functional surface opposite to each other,
the non-functional surface is in contact with the flexible substrate;
the functional surface of the threaded area includes a plurality of raised rings;
the plurality of raised rings surround the central area;
the plurality of raised rings are distributed in concentric rings; and
the functional surface of the central area includes a convex transparent structure.

3. The laser source according to claim 2, wherein:
cross-sectional shapes of the plurality of raised rings include a first sawtooth shape; or
a cross-sectional shape of the convex transparent structure includes a half-circle.

4. The laser source according to claim 3, wherein:
a tooth back of the first sawtooth is recessed toward the non-functional surface; or
a tooth back of the first sawtooth protrudes in a direction away from the functional surface; or
a cross-sectional shape of the convex transparent structure includes a second sawtooth shape; and
a width of the second sawtooth is greater than a width of the first sawtooth.

5. The laser source according to claim 2, wherein:
a plurality of vertical cavity surface-emitting laser source units corresponding to the central area have a first row spacing and a first column spacing;
a plurality of vertical cavity surface-emitting laser source units corresponding to the threaded area have a second row spacing and a second column spacing;
the first row spacing is different from the second row spacing; and
the first column spacing is different from the second column spacing.

6. The laser source according to claim 5, wherein:
the first row spacing is greater than the second row spacing; and
the first column spacing is greater than the second column spacing.

7. The laser source according to claim 1, wherein:
row spacings of a plurality of rows of vertical-cavity surface-emitting laser source units are same; and
column spacings of a plurality of columns of vertical-cavity surface-emitting laser source units are same.

8. The laser source according to claim 1, comprising:
a first part; and
a second part,
wherein:
the first part and the second part are bent with different radii of curvature, or
the first part and the second part are bent with the same radii of curvature.

9. The laser source according to claim 8, wherein:
the prism structure and the flexible substrate are bent toward the second surface of the flexible substrate; and
a radius of curvature ranges from 1 cm to 10 cm.

10. The laser source according to claim 1, further comprising:
a plurality of thin-film transistors arranged on the first surface of the flexible substrate,
wherein:
the plurality of thin-film transistors are electrically connected to the plurality of vertical-cavity surface-emitting laser source units; and
the plurality of thin-film transistors are configured to control whether the plurality of vertical-cavity surface-emitting laser source units are turned on or off.

11. The laser source according to claim 1, further comprising:
an optical glue layer arranged between the first surface of the flexible substrate and the prism structure, and configured to glue the prism structure to the flexible substrate, wherein the optical glue layer also covers a top plate surface and side wall surfaces of the plurality of vertical-cavity surface-emitting laser source units.

12. The laser source according to claim 11, wherein:
a thickness of the optical glue layer is greater than a thickness of a vertical-cavity surface-emitting laser light source unit.

13. The laser source according to claim 1, further comprising:
a rotation structure,
wherein:
the flexible substrate is arranged on a surface of the rotation structure; and
the flexible substrate partially surrounds the surface of the rotation structure or fully surrounds the surface of the rotation structure along a rotation direction of the rotation structure.

14. The laser source according to claim 1, wherein:
a thickness of the prism structure is greater than or equal to 1 mm.

15. A method for forming a laser source, comprising:
providing a flexible substrate including a first surface and a second surface opposite to each other;
providing a plurality of vertical-cavity surface-emitting laser source units;
performing a mass transfer process to arrange the plurality of vertical-cavity surface-emitting laser source units on the first surface of the flexible substrate, and distribute the plurality of vertical-cavity surface-emitting laser source units in rows and columns;
providing a prism structure, and fitting the prism structure to the flexible substrate with the first surface of the flexible substrate facing the prism structure; and
bending the prism structure and the flexible substrate toward the second surface of the flexible substrate.

16. An imaging method of a laser source, comprising:
proving a laser source including a flexible substrate including a first surface and a second surface opposite to each other; a plurality of vertical-cavity surface-emitting laser source units arranged on the first surface of the flexible substrate and being arranged in rows and columns; and a prism structure attached to the flexible substrate, wherein the first surface of the flexible substrate faces the prism structure, and the prism structure and the flexible substrate are bent toward the second surface of the flexible substrate;
imaging a static object according to the laser source; and
imaging a dynamic object according to the laser source.

17. The imaging method according to claim 16, wherein imaging the static object according to the laser light source comprises:
emitting laser to a surface of an object using the plurality of vertical-cavity surface-emitting laser source units, each of the plurality of vertical-cavity surface-emitting laser source units including a corresponding emission angle;
receiving reflected light from the surface of the object using a laser receiver, each reflected light including a corresponding reflection angle;
converting an optical signal into an electrical signal using the laser receiver;
processing the electrical signal into a plurality of frames of light spot images using an image processor, the plurality of frames of light spot images including a plurality of reflected light spots;
obtaining a vertical-cavity surface-emitting laser light source unit corresponding to the reflected light spot using the image processor and calculating coordinates of the reflected light spot through an incident angle and a reflection angle; and
imaging the static object according to the plurality of coordinates.

18. The imaging method according to claim 17, wherein:
emitting laser to the surface of the object using the plurality of vertical-cavity surface-emitting laser source units includes the plurality of vertical-cavity surface-emitting laser source units emit laser light at the same time, or the plurality of vertical-cavity surface-emitting laser source units emit laser light in a time sequence.

19. The imaging method according to claim 17, wherein:
the plurality of the vertical-cavity surface-emitting laser source units emit laser in sequence;
each of the plurality of vertical-cavity surface-emitting laser source units has a corresponding light emission sequence; and
a process for the image processor to obtain the vertical cavity surface-emitting laser source unit corresponding to the reflected light spot includes obtaining a light emission history of the reflected light spot at a preset moment; calculating a light-emission sequence of the reflected light spot according to the light-emission history and the preset moment; and obtaining the corresponding vertical-cavity surface-emitting laser source unit according to the light-emission sequence.

20. The imaging method according to claim 19, wherein imaging the dynamic object according to the laser source comprises:
emitting laser in the time sequence using the plurality of vertical-cavity surface-emitting laser source units, wherein each vertical-cavity surface-emitting laser source unit has a corresponding emission angle;
receiving reflected light from the surface of the object using a laser receiver, wherein each reflected light has a corresponding reflection angle;
converting an optical signal into an electrical signal using a laser receiver;
processing the electrical signal into a plurality of frames of light spot images using an image processor;
determining that a new light spot has appeared when the position coordinates of two adjacent frames of light spot images are different; and
imaging the dynamic object according to a plurality of new light spots.
